(19) United States
(12) Patent Application Publication
(10) Pub. No.: US 2006/0214174 A1
(43) Pub. Date: Sep. 28, 2006

(54) Backlight apparatus and liquid crystal display apparatus

(75) Inventors: Toshiaki Shirakuma, Chiba (JP); Masami Okita, Tokyo (JP)

Correspondence Address: ROBERT J. DEPKE;LEWIS T. STEADMAN, ROCKEY, DEPKE, LYONS AND KITZINGER, LLC, SUITE 5450 SEARS TOWER, CHICAGO, IL, 60606-6306, US

(73) Assignee: SONY CORPORATION

(21) Appl. No.: 11/358,463

(22) Filed: Feb. 21, 2006

(30) Foreign Application Priority Data
Mar. 25, 2005 (JP) P2005-089492

(51) Int. Cl. H01L 29/00

(52) U.S. Cl. 257/89; 349/65; 257/E25.032

(57) ABSTRACT

The present invention has been made to reduce manufacturing cost of a liquid crystal display apparatus. The present invention provides a backlight apparatus including an LED chip substrate on which a plurality of red-LED (Light Emitting Diode) chips that emit red light, green-LED chips that emit green light, and blue-LED chips that emit blue light are arranged in a given manner, a diffusion section that is provided above the LED chip substrate and diffuses respective color lights emitted from the LED chips, a light amount detection section that detects the amount of the light emitted from the LED chip substrate, and an adjustment section that adjusts the amount of the current to be supplied to the LED chip substrate based on the light amount detected by the light amount detection section.

### CROSS REFERENCE TO RELATED APPLICATIONS

The present invention contains subject matter related to Japanese Patent Application JP 2005-089492 filed in Japanese Patent Office on Mar. 25, 2005, the entire contents of which being incorporated herein by reference.

### BACKGROUND OF THE INVENTION

1. Field of the Invention

The present invention relates to a backlight apparatus that illuminates a liquid crystal display section from the back thereof and a liquid crystal display apparatus including the backlight apparatus.

2. Description of the Related Art

A liquid crystal display has some advantages, as compared to a CRT (Cathode-Ray Tube) screen. For example, an increase in the display size, and a reduction in the weight, thickness, and power consumption can be easily improved. Therefore, the liquid crystal display has increasingly been used for a television set and various types of displays together with, for example, a self-luminous PDP (Plasma Display Panel). In the liquid crystal panel, a liquid crystal is encapsulated between two transparent substrates having various sizes, and a predetermined voltage is applied to change the direction of the liquid crystal molecules to thereby change the light transmittance to allow a predetermined image and the like to be visualized optically.

Since the liquid crystal itself is not a luminous body, the liquid crystal display apparatus has a backlight unit functioning as a light source at the back of a liquid crystal panel. The backlight unit includes, for example, a primary light source, a light guide panel, a reflection film, a lens sheet or a diffusion film, and the like and supplies a display light to the entire liquid crystal panel. In the backlight unit, a CCFL (Cold Cathode Fluorescent Lamp) obtained by encapsulating mercury or xenon in a fluorescent tube is used as a primary light source. However, there are some problems with the CCFL, such as low emission brightness, short lifetime, or poor brightness uniformity due to existence of the low brightness area on the cathode side.

A large-sized liquid crystal display apparatus is generally provided with an area light configuration backlight apparatus in which a plurality of long CCFLs are arranged at the back surface of a diffusion panel to supply a display light to the liquid crystal panel. Also in the area light configuration backlight apparatus, the above problem caused by the CCFL must be solved. In particular, in a large-sized television set with a screen 40 inches or larger, increases in the brightness and brightness uniformity are strongly demanded.

In the field of the area light configuration backlight apparatus, an LED (Light Emitting Diode) area light configuration backlight has gotten a lot of attention recently, in which a large number of LEDs of red, green, and blue (light's three primary colors) are two-dimensionally arranged at the backside surface of the diffusion panel in place of the above mentioned CCFLs to obtain a white light. In the LED backlight apparatus, manufacturing cost thereof has been reduced along with the cost reduction of LED and, further, high brightness display is available on a large-sized liquid display panel with low power consumption.

In various types of backlight apparatuses, various kinds of optical members that convert the function of the display light emitted from a light source and equalize it, such as an optical function sheet block, a diffusion light guide plate, a light diffusion plate, or reflection sheet, are provided between an light source unit and a transmissive liquid crystal panel. In the backlight apparatus, the light diffusion plate is generally formed of a transparent acrylic resin, in which a light control pattern having a function of transmitting a part of the display light that enters a site facing the light source and reflecting a part thereof is formed. The invention disclosed in Jpn. Pat. Appln. Laid-Open Publication No. 6-301034 includes a light diffusion plate in which each of a plurality of light control patterns to be formed in the area that faces a fluorescent tube is constituted by a number of reflection dots. When the light diffusion plate is formed so as the area of the reflection dot becomes smaller as it is away from the axis line of the fluorescent tube, the light transmittance becomes higher with distance from the axis line of the fluorescent tube, with the result that a uniformed light can be obtained as a whole.

### SUMMARY OF THE INVENTION

In the abovementioned backlight apparatus, respective LED chips of red-LED, green-LED, and blue-LED are individually packaged (shell-type LED, etc.) (see FIG. 1). The LED chip packages 30 are mounted on printed circuit boards respectively, the printed circuit boards are then attached to a backlight apparatus main body, and the printed circuit boards are connected to each other by wirings.

Depending on the size of the backlight apparatus, in general, the backlight apparatus main body includes about 8 to 20 printed circuit boards mounting about 200 to 400 LEDs. The backlight apparatus originally aimed is to emit a planar light and thereby obtain a uniform white light. Therefore, in the above case, it is necessary to provide an optical system that mixes the respective colors in order to obtain a uniform white light. Accordingly, a certain degree of thickness is required for the backlight apparatus.

When the size of the backlight apparatus is increased, it is necessary to provide thousands of LEDs, resulting in a fairy large weight.

The present invention has been made in view of the above problems, and it is desirable to provide a backlight apparatus and a liquid crystal display apparatus in which the thicknesses can be reduced and the weights can be suppressed even if the sizes thereof are increased.

To solve the above problem, according to the present invention, there is provided a backlight apparatus including: an LED chip substrate on which a plurality of red-LED (Light Emitting Diode) chips that emit red light, green-LED chips that emit green light, and blue-LED chips that emit blue light are arranged in a given manner; a diffusion means that is provided above the LED chip substrate and for diffusing respective color lights emitted from the LED chips; a light amount detection means for detecting the amount of the light emitted from the LED chip substrate; and an adjustment means for adjusting the amount of the current to be supplied to the LED chip substrate based on the light amount detected by the light amount detection means.

According to the present invention, there is provided a liquid crystal display apparatus including a backlight apparatus that illuminates a liquid crystal display panel from the back surface side thereof, the backlight apparatus including: an LED chip substrate on which a plurality of red-LED (Light Emitting Diode) chips that emit red light, green-LED chips that emit green light, and blue-LED chips that emit blue light are arranged in a given manner; a diffusion means that is provided above the LED chip substrate and for diffusing respective color lights emitted from the LED chips; a light amount detection means for detecting the amount of the light emitted from the LED chip substrate; and an adjustment means for adjusting the amount of the current to be supplied to the LED chip substrate based on the light amount detected by the light amount detection means.

In the present invention, it is possible to simplify the wiring of the backlight unit using a bonding technique. Further, since unpackaged LED chips are used, manufacturing cost can be reduced.

Further, in the present invention, unpackaged LED chips are used for the backlight unit, that is, the LED chips are directly mounted. Therefore, it is possible to realize weight saving by the weight corresponding to the LED packages, as compared to the case of the conventional backlight unit. This can also contribute to a reduction in the thickness of the backlight unit.

### BRIEF DESCRIPTION OF THE DRAWINGS

FIG. 1 is a view showing packaged LED chips;

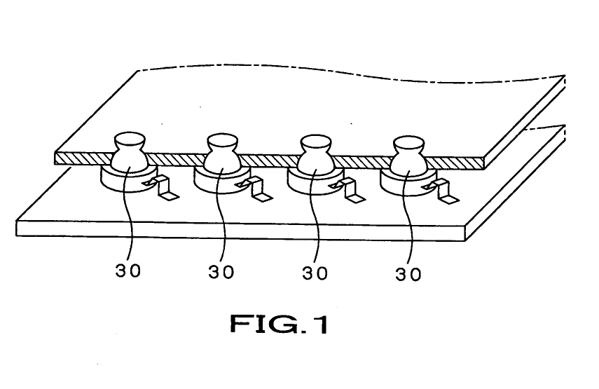

FIG. 2 is an exploded perspective view showing the main part of a transmissive liquid crystal display panel according to an embodiment of the present invention;

FIG. 3 is a view showing a configuration example of a light emitting block;

FIG. 4 is a vertical cross-sectional view showing the main part of the transmissive liquid crystal display panel; and

FIG. 5 is a block diagram showing a configuration of an adjustment unit that adjusts the white balance of a light emitted from a backlight unit.

### DETAILED DESCRIPTION OF THE PREFERRED EMBODIMENTS

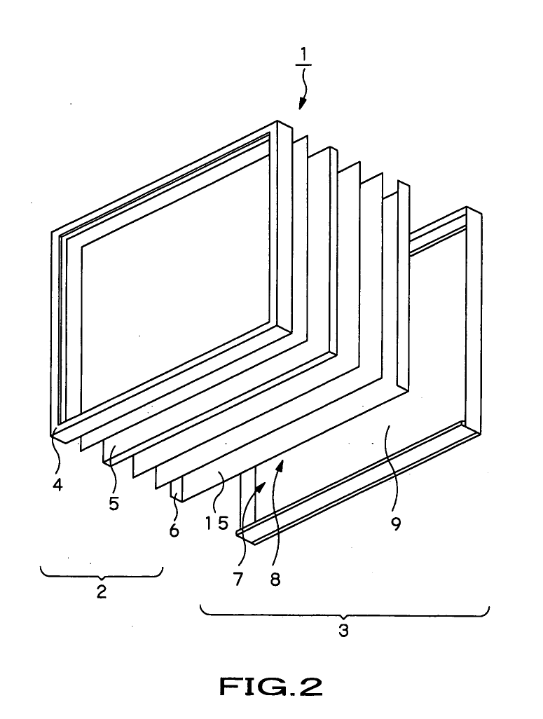

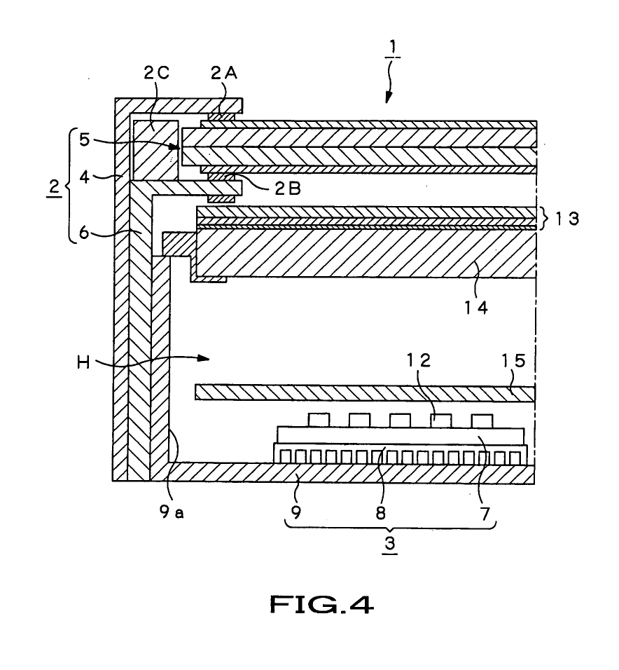

A transmissive liquid crystal display panel 1 shown in the accompanying drawings will be described in detail below as an embodiment of the present invention. The transmissive liquid crystal display panel 1 is used, for example, as a display panel of a television set with a large screen 40 inches or larger. As shown in FIGS. 2 and 4, the transmissive liquid crystal display panel 1 includes a liquid crystal panel unit 2 and a backlight unit 3 mounted on the back surface side of the liquid crystal panel unit 2 and supplies a display light thereto. The liquid crystal panel unit 2 includes a front frame member 4, a liquid crystal panel 5, and a back frame member 6 that holds the periphery of the liquid crystal panel 5 by sandwiching the same with the front frame member 4 through spacers 2A, 2B, and a guide member 2C.

Although the detail is omitted here, the liquid crystal panel 5 encapsulates a liquid crystal between first and second glass substrates whose opposed interval is held by spacer beads or the like and applies a voltage to the liquid crystal to change the direction of liquid crystal molecules to thereby change the light transmittance. On the inner surface of the first glass substrate of the liquid crystal panel 5, a striped transparent electrode, an insulating film, and an oriented film are formed. On the inner surface of the second glass substrate of the liquid crystal panel 5, a three primary color filter, an overcoat layer, a striped transparent electrode, and an oriented film are formed. A deflection film and a phase difference film are attached to the surfaces of the first and second glass substrates.

In the liquid crystal panel 5, the oriented film made of polyimide is used to arrange the liquid crystal molecules on its boundary surface in the horizontal direction, the deflection film and phase difference film are used to achromatize and whiten the wavelength characteristic, the color filter is used for full-colorization and, thereby, a reception image or the like is displayed in full color. The configuration of the liquid crystal panel 5 is not limited to the above and it goes without saying that liquid crystal panels having various types of configurations that have been conventionally proposed can be used.

The backlight unit 3 includes a light emitting unit 7 that is disposed on the back surface side of the abovementioned liquid crystal panel unit 2 and supplies a display light thereto, a heat radiating unit 8 that radiates heat generated in the light emitting unit 7, and a back panel 9 that holds the light emitting unit 7 and heat radiating unit 8 as well as being combined with the front frame member 4 and back frame member 6 to thereby constitute an attachment member with respect to the chassis. The backlight unit 3 has an outside dimension that allows the entire surface thereof to face the back surface of the liquid crystal panel unit 2. The backlight unit 3 and liquid crystal panel unit 2 are combined with each other with the opposed space between them optically sealed.

In the backlight unit 3, the light-emitting unit 7 includes an optical sheet block 10 and a light emitting block 11 having a large number of LED chips. In the present invention, unpackaged LED chips are used.

The detail of the light emitting block 11 will be described later. The optical sheet block 10 is disposed opposite to the back surface of the liquid crystal panel 5. Although the detail is omitted, the optical sheet block 10 includes an optical function sheet laminated body 13 obtained by laminating various types of optical function sheets such as a deflection film, phase difference film, prism sheet, or diffusion film, a diffusion light guide plate 14, a diffusion plate 15, a reflection sheet 16 that reflects a light, and the like. The optical function sheet laminated body 13 is constituted by laminating a plurality of optical function sheets that have various optical functions, such as a function sheet that breaks a display light that is supplied from the light emitting block 11 and enters the liquid crystal panel 5 into orthogonal deflection components, a function sheet that compensates the phase difference in a light wave to widen the field of view angle and to prevent coloration, or a function sheet that diffuses a display light. The components of the optical function sheet laminated body 13 are not limited to the above. For example, the optical function sheet laminated body 13 may include a brightness enhancement film that enhances brightness, or two upper and lower diffusion sheets that sandwich the phase different film or prism sheet.

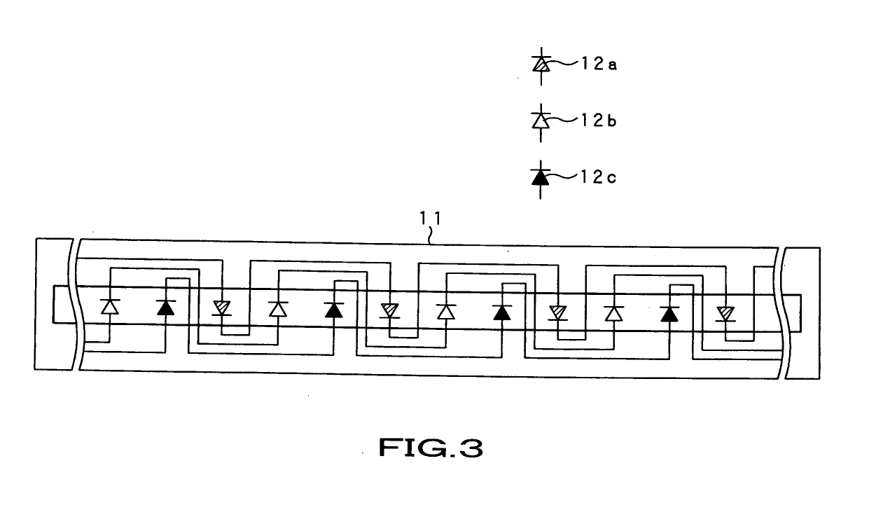

FIG. 3 shows an example of an arrangement of the LED chips 12. As shown in FIG. 3, in the light emitting block 11, appropriate numbers of red-LED chips 12a, green-LED chips 12b, and blue-LED chips 12c are connected in cascade on a wiring board 12a with their polarities indicating the same direction on a per color basis. The light emitting block 11 mounting a given number of LED chips 12 is set as one unit, and a plurality of the units constitute the backlight unit 3. The red-LED chip 12a, green-LED chip 12b, and blue-LED chip 12c have parameters indicating a wavelength temperature dependence of within ±50K (kelvin), respectively.

Although the red-LED chips 12a, green-LED chips 12b, and blue-LED chips 12c are alternately arranged in the arrangement example of the LED chips 12 shown in FIG. 3, the present invention is not limited to this. The number of LED chips 12 to be mounted in one unit and combination thereof are appropriately determined depending on the size of a display screen or the light emitting capability of the LED chips 12.

In the optical sheet block 10, the diffusion light guide plate 14 is disposed on the main surface side in which the optical function sheet laminated body 13 faces the liquid crystal panel 5 in a laminated state. A display light supplied from the light emitting block 11 enters the back surface of the diffusion light guide plate 14. The diffusion light guide plate 14 is formed by a slightly thick plate body made of a transparent synthetic resin having a light guiding characteristics, for example, acrylic resin or polycarbonate resin. The diffusion light guide plate 14 refracts and reflects the display light that has entered from one main surface side inside thereof to guide the light while diffusing it and allows the light to enter the optical function sheet laminated body 13 from the other main surface. As shown in FIG. 4, the diffusion light guide plate 14 and optical function sheet laminated body 13 are attached to an outer peripheral wall 9a of the back panel 9 through a bracket member 14A.

In the optical sheet block 10, the diffusion plate 15 and reflection sheet 16 are attached to the back panel 9 with opposed interval between them and the diffusion light guide plate 14 held by not shown a large number of optical stud members. The diffusion plate 15 is a plate member made of a transparent synthetic resin, for example, acrylic resin. The display light supplied from the light emitting block 11 enters the diffusion light.

In the optical sheet block 10, a part of the display light emitted from the LED chips 12 is diffused to the surrounding area by the diffusion plate 15 to prevent a high power display light from directly entering a part of the diffusion light guide plate 14, which prevents the brightness of the diffusion light guide plate 14 from being increased partially. In the optical sheet block 10, the display light diffused to the surrounding area by the diffusion plate 15 is reflected by the reflection sheet 16 toward the diffusion light guide plate 14 through the diffusion plate 15, thereby increasing light efficiency. The reflection sheet 16 is formed by foamable PET (polyethylene terephthalate) including a fluorescent material. The foamable PET has a reflectance ratio as high as about 95%. Further, the foamable PET takes on a different tone color from a metallic color, making scratches on the reflection surface less noticeable. The reflection sheet 16 is formed by silver having a mirror surface, aluminum, stainless steel, or the like.

In the optical sheet block 10, when a part of the display light emitted from the LED chips 12 enters the diffusion plate 15 with an incident angle exceeding the critical angle, it is allowed to be reflected by the surface of the diffusion plate 15. In the optical sheet block 10, the reflected light from the surface of the diffusion plate 15 or a part of the display light emitted from the LED chips 12, diffused to the surrounding area, and reflected by the reflection sheet 16 is repeatedly reflected between the diffusion plate 15 and reflection sheet 16, thereby increasing reflectance ratio according to multiple reflection principle.

A configuration of an adjustment unit 20 that adjusts the white balance of the backlight unit 3 will be described.

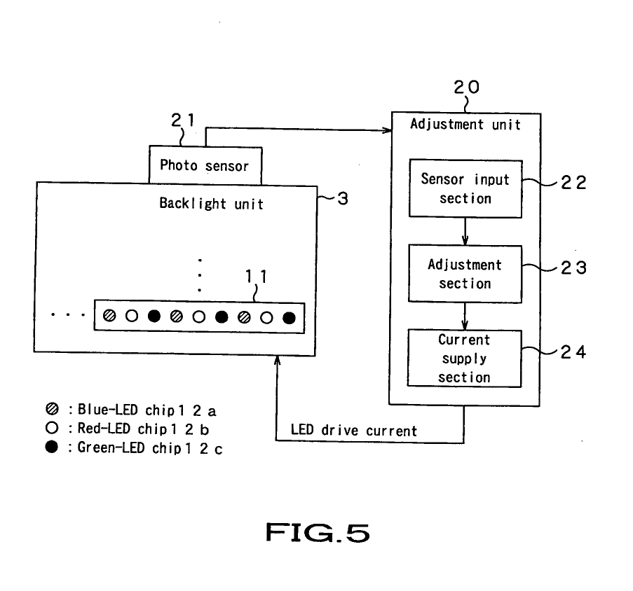

As shown in FIG. 5, the adjustment unit 20 includes a sensor input section 22 that inputs the detection value of a photo sensor 21 that detects the light emission amount of the LED chips 12, an adjustment section 23 that adjusts the white balance of the backlight unit 3, and a current supply section 24 that supplies a current to the LED chips 12 in accordance with a result of the operation of the adjustment section 23.

The photo sensor 21 detects the light emission amount of the LED chips 12 of the light emitting block 11 that constitutes the backlight unit 3 and supplies the detected light emission amount to the sensor input section 22. The photo sensor 21 may be directly disposed on the light emitting block 11 mounting a given number of LED chips. Further, the photo sensor 21 detects the white light reflected by the diffusion plate 15.

The adjustment section 23 determines the amount of the current to be supplied to the red-LED chip 12a, green-LED chip 12b, and blue-LED chip 12c based on the detected values of the LED chips 12 input through the sensor input section 22. The adjustment section 23 then supplies determined current values of the LED chips 12 to the current supply section 24. The adjustment section 23 extracts brightness and chromaticity information for obtaining a desired white balance based on the detection value of the photo sensor 21 supplied from the sensor input section 22.

The current supply section 24 supplies a current to the backlight unit 3 according to the current values of the LED chips 12 supplied from the adjustment section 23.

As described above, the transmissive liquid crystal display panel 1 according to the present invention includes the backlight unit 3, the backlight unit 3 being attached to the back surface side of the liquid crystal panel unit 2 to supply a display light to the liquid crystal panel unit 2 and including the light emitting block 11 in which a plurality of unpackaged red-LED chips 12a, green-LED chips 12b, and blue-LED chips 12c are arranged in cascade. With this configuration, it is possible to simplify the wiring of the backlight unit 3 using a bonding technique. Further, since unpackaged LED chips are used, manufacturing cost can be reduced.

Further, in the present invention, the LED chips are directly mounted. Therefore, it is possible to realize weight saving by the weight corresponding to the LED packages even in the case where thousands of LED chips are mounted according to design requirements, as compared to the case of the conventional backlight unit.

Further, in the present invention, unpackaged LED chips are used. Therefore, by using small-sized LED chips and arranging them with the interval between them being closed, the backlight unit 3 can include more LED chips, as compared to the conventional backlight unit having the same size, with the result that it is possible to increase brightness and color uniformity. This can eliminate the optical system that the conventional backlight unit has required for the increase in brightness and color uniformity. Further, by appropriately controlling the distance between the diffusion plate 15 and light emitting unit 7, the thickness of the backlight unit can be reduced.

Further, in the present invention, by mounting a drive circuit for energizing the LED chips on the same substrate on which the LED chips are mounted, it is possible to eliminate the need of additionally providing a drive substrate.

The light intensity of the LED has a property of changing with temperature and time. In order to cope with this, the following configuration may be adopted in the present invention. That is, the photo sensor 21 that detects a light emitted from the red-LED chip 12a, green-LED chip 12b, and blue-LED chip 12c is mounted on the light emitting block 11, as well as the adjustment unit 20 that determines the amount of the current to be supplied to the red-LED chip 12a, green-LED chip 12b, and blue-LED chip 12c based on the light amount detected by the photo sensor is mounted on the light emitting block 11, thereby constituting a control section that controls the adjustment section 20 based on the light amount detected by the photo sensor 21 to maintain the brightness and chromaticity of the light emitted from the light emitting block 11 constant.

It should be understood by those skilled in the art that various modifications, combinations, sub-combinations and alternations may occur depending on design requirements and other factors insofar as they are within the scope of the appended claims or the equivalents thereof.

What is claimed is:

1. A backlight apparatus comprising:
an LED chip substrate on which a plurality of red-LED (Light Emitting Diode) chips that emit red light, green-LED chips that emit green light, and blue-LED chips that emit blue light are arranged in a given manner;
diffusion means that is provided above the LED chip substrate and for diffusing respective color lights emitted from the LED chips;
light amount detection means for detecting the amount of the light emitted from the LED chip substrate; and
adjustment means for adjusting the amount of the current to be supplied to the LED chip substrate based on the light amount detected by the light amount detection means.

2. The backlight apparatus according to claim 1, wherein the red-LED chip, green-LED chip, and blue-LED chip have parameters indicating a wavelength temperature dependence of within ±50K (kelvin), respectively.

3. The backlight apparatus according to claim 1, wherein the light amount detection means detects the amount of the light emitted from the red-LED chips, green-LED chips, and blue-LED chips.

4. The backlight apparatus according to claim 3, wherein the light amount detection means includes extraction means for extracting brightness and chromaticity information from the detected amount of the light emitted from the red-LED chips, green-LED chips, and blue-LED chips.

5. The backlight apparatus according to claim 1, wherein the adjustment means adjusts the amount of the current to be supplied to the red-LED chips, green-LED chips, and blue-LED chips.

6. A liquid crystal display apparatus comprising a backlight apparatus that illuminates a liquid crystal display panel from the back surface side thereof,
the backlight apparatus comprising:
an LED chip substrate on which a plurality of red-LED (Light Emitting Diode) chips that emit red light, green-LED chips that emit green light, and blue-LED chips that emit blue light are arranged in a given manner;
diffusion means that is provided above the LED chip substrate and for diffusing respective color lights emitted from the LED chips;
light amount detection means for detecting the amount of the light emitted from the LED chip substrate; and
adjustment means for adjusting the amount of the current to be supplied to the LED chip substrate based on the light amount detected by the light amount detection means.

7. A backlight apparatus comprising:
an LED chip substrate on which a plurality of red-LED (Light Emitting Diode) chips that emit red light, green-LED chips that emit green light, and blue-LED chips that emit blue light are arranged in a given manner;
a diffusion section that is provided above the LED chip substrate and diffuses respective color lights emitted from the LED chips;
a light amount detection section that detects the amount of the light emitted from the LED chip substrate; and
an adjustment section that adjusts the amount of the current to be supplied to the LED chip substrate based on the light amount detected by the light amount detection section.

8. A liquid crystal display apparatus comprising a backlight apparatus that illuminates a liquid crystal display panel from the back surface side thereof,
the backlight apparatus comprising:
an LED chip substrate on which a plurality of red-LED (Light Emitting Diode) chips that emit red light, green-LED chips that emit green light, and blue-LED chips that emit blue light are arranged in a given manner;
a diffusion section that is provided above the LED chip substrate and diffuses respective color lights emitted from the LED chips;
a light amount detection section that detects the amount of the light emitted from the LED chip substrate; and
an adjustment section that adjusts the amount of the current to be supplied to the LED chip substrate based on the light amount detected by the light amount detection section.
